(19) United States
(12) Patent Application Publication
(10) Pub. No.: US 2026/0082525 A1
(43) Pub. Date: Mar. 19, 2026

(54) INTEGRATED COOLANT MODULE

(71) Applicant: Hanon Systems, Daejeon (KR)

(72) Inventors: Jungbum CHOI, Daejeon (KR); Seong Woo JEONG, Daejeon (KR); Ho Sung KANG, Daejeon (KR); Sung Geun SHIN, Daejeon (KR); Byung Seon CHO, Daejeon (KR); Moon-Seok CHOI, Daejeon (KR); Jeong Wan HAN, Daejeon (KR)

(73) Assignee: Hanon Systems, Daejeon (KR)

(21) Appl. No.: 19/101,499

(22) PCT Filed: Jul. 11, 2023
(86) PCT No.: PCT/KR2023/009876

§ 371 Date: Feb. 5, 2025

(30) Foreign Application Priority Data
Aug. 29, 2022 (KR) 10-2022-0108179

(51) Int. Cl. H05K 7/20

(52) U.S. Cl. CPC H05K 7/20872

(57) ABSTRACT

The present invention relates to an integrated coolant module applied to a thermal management system of a vehicle and, more specifically, to a structure for coolant connection and fixation between a reservoir tank and a coolant control module. According to the present invention, a through-hole is formed through the side of the reservoir tank, a coolant pipe is formed on the side of the coolant control module, and a structure for connecting the through-hole and the coolant pipe is adopted, so that the width of a coolant passage is uniformly configured. Therefore, the present invention can solve a pressure loss problem due to a difference in the internal diameter of the coolant passage.

### TECHNICAL FIELD

The present invention relates to an integrated coolant module applied to a thermal management system for a vehicle, and more specifically, to a coolant connection and fixing structure between a reservoir tank and a coolant control module.

### BACKGROUND ART

Recently, due to the electrification of vehicles, the need for thermal management of electrical components such as a vehicle interior, a battery, a motor, and the like has greatly expanded. Accordingly, the thermal management system for a vehicle is becoming more complex to independently perform thermal management for each component and at the same time, integrate the overall thermal management of the vehicle to increase thermal efficiency.

To perform such integrated thermal management of a vehicle, it is necessary to integrate and modularize complex coolant lines and components, and thus a coolant module that integrates a reservoir tank for storing coolant, a pump for pressing and transporting the coolant, and a valve for controlling a flow direction and flow amount of the coolant is being proposed.

FIG. 1 is a schematic view illustrating a conventional coolant module, and a conventional coolant module 90 includes a reservoir tank 91 in which coolant is stored and accommodated, a valve 92 fluidly connected to the reservoir tank, and a pump 93 fluidly connected to the valve.

As illustrated, conventionally, a coolant entrance pipe 91P is provided at the reservoir tank 91 side, a separate coolant entrance pipe 92P is provided on the valve 92 (or the pump, hereinafter limited to the valve) side, and the pipe 91P at the reservoir tank side is coupled by being inserted into the pipe 92P at the valve side, thereby forming a structure in which coolant is communicated between the reservoir tank 91 and the valve 92. In addition, a fixing member 95 for fixing the reservoir tank and the valve is provided near a connection portion of the pipes 91P and 92P.

In this case, the reservoir tank 91 is manufactured by injection molding, and when the coolant entrance pipe 91P is formed on the reservoir tank 91 by injection molding, a minimum space for forming the corresponding pipe 91P is required near the pipe 91P, and thus an area in which structural forming is impossible is present in a predetermined area near the pipe. FIG. 2 is a view illustrating a pipe at a reservoir tank side and a fixing member, and as illustrated, a mold required space PP is present in a predetermined area near the pipe, and thus there is a problem that the fixing member 95 for fixing the reservoir tank and the valve cannot be disposed close to the pipes 91P and 92P.

In addition, FIG. 3 is an enlarged view of the connection portion between the pipes in FIG. 1, and as illustrated, when the pipe 91P at the reservoir tank side is inserted into the pipe 92P at the valve side, an inner diameter of the pipe 92P at the valve side differs from an inner diameter of the pipe 91P at the reservoir tank side, and thus there is a problem that pressure loss occurs at a connection point between the two pipes.

### Related Art Document

(Patent Document 1) Korean Laid-Open Patent No. 10-2022-0043563 (2022.04.05.)

### Technical Problem

The present invention has been made in efforts to solve the above problems and is directed to providing an integrated coolant module, which is capable of solving a pressure loss problem due to a difference of inner diameters in a coolant passage by forming a through-hole at a reservoir tank side, forming a coolant pipe at a coolant control module side, and adopting a structure for connecting the through-hole to the coolant pipe to form a constant width of the coolant passage.

### Technical Solution

An integrated coolant module according to one embodiment of the present invention may include a reservoir tank in which coolant is stored and a coolant control module including a valve and a pump, wherein a through-hole that penetrates one surface of the reservoir tank as a coolant entrance may be formed at the reservoir tank side, a coolant pipe formed to protrude from one side of the coolant control module as a coolant entrance may be provided at the coolant control module side, and the through-hole and the coolant pipe may be connected and formed so that coolant flows between the reservoir tank and the coolant control module.

A protrusion rib having a pipe structure surrounding the through-hole may be provided on the one surface of the reservoir tank, an inner diameter of the protrusion rib may be formed to be larger than a diameter of the through-hole so that an outer circumferential wall of the protrusion rib is disposed to be radially spaced a predetermined distance from the through-hole, a ring-shaped ring portion of the one surface of the reservoir tank may be formed between the protrusion rib and the through-hole, and an end portion of the coolant pipe may be inserted into the protrusion rib.

An inner diameter of the coolant pipe may be equal to the diameter of the through-hole.

A thickness of the coolant pipe may be equal to a width of the ring portion.

A front end of the coolant pipe may be seated on the ring portion.

A connection portion between the protrusion rib and the coolant pipe may be provided with at least one of an O-ring interposed between an inner circumferential surface of the protrusion rib and an outer circumferential surface of the coolant pipe to seal the coolant pipe with a lateral pressure, and a ring gasket interposed between the ring portion and a front end of the coolant pipe to seal the coolant pipe with a surface pressure.

The through-hole, the protrusion rib, and the coolant pipe may each be formed as two, and when one of the two through-holes is referred to as a first through-hole and the other is referred to as a second through-hole, a protrusion rib corresponding to the first through-hole among the two protrusion ribs is referred to as a first protrusion rib and a protrusion rib corresponding to the second through-hole is referred to as a second protrusion rib, and a coolant pipe corresponding to the first through-hole among the two coolant pipes is referred to as a first coolant pipe and a coolant pipe corresponding to the second through-hole is referred to as a second coolant pipe, one of a first connection portion between the first protrusion rib and the first coolant pipe and a second connection portion between the second protrusion rib and the second coolant pipe may have only the O-ring among the O-ring and the ring gasket, and the other may have only the ring gasket among the O-ring and the ring gasket.

A fixing block for fixing the coolant pipe to the protrusion rib may be provided on the one surface of the reservoir tank and near the protrusion rib, the coolant pipe may be provided with a fixing bracket to correspond to the fixing block so that the coolant pipe inserted into the protrusion rib is fixed through the fixing block and the fixing bracket, and the fixing block may be disposed adjacent to the protrusion rib.

The fixing block may be formed to protrude outward from the one surface of the reservoir tank, and at least a part of the fixing block may be in contact with an outer circumferential surface of the protrusion rib.

A height of the fixing block may be equal to a height of the protrusion rib.

The fixing block may be formed to protrude inward from the one surface of the reservoir tank, and at least a part of the fixing block may be positioned colinearly with an outer circumferential wall of the protrusion rib.

The fixing block may be formed as one corresponding to the protrusion rib.

The reservoir tank may be provided with an additional fixing block for fixing the coolant control module and the reservoir tank, and the additional fixing block may be disposed in a direction opposite to the fixing block so that the through-hole is disposed between the additional fixing block and the fixing block.

The one surface of the reservoir tank may be formed to have a constant thickness over the entire area.

The reservoir tank and the protrusion rib may be manufactured by injection-molding and formed integrally.

### Advantageous Effects

According to the present invention, it is possible to solve the pressure loss problem due to the difference of the inner diameters in the coolant passage by forming the through-hole at the reservoir tank side, forming the coolant pipe at the coolant control module side, and adopting the structure for connecting the through-hole to the coolant pipe to form the constant width of the coolant passage.

In addition, by forming the through-hole and the protrusion rib at the reservoir tank side and adopting the coupling method of inserting the coolant pipe at the coolant control module side into the corresponding protrusion rib, the fixing block for fixing the reservoir tank and the coolant control module can be disposed close to the pipe, thereby improving spatiality, ease of coupling, and the like.

### DESCRIPTION OF DRAWINGS

FIG. 1 is a schematic view illustrating a conventional coolant module.

FIG. 2 is a view illustrating a pipe at a reservoir tank side and a fixing member.

FIG. 3 is an enlarged view illustrating a connection portion between pipes in FIG. 1.

FIG. 4 is a view illustrating an integrated coolant module according to one embodiment of the present invention.

FIG. 5 is an enlarged view illustrating portion C in FIG. 4.

FIG. 6 is a perspective view illustrating one surface of a reservoir tank of portion C in FIG. 4.

FIG. 7 is a view for describing a fixing structure according to another embodiment of the present invention.

FIG. 8 is a view illustrating one surface of the reservoir tank according to one surface of the present invention.

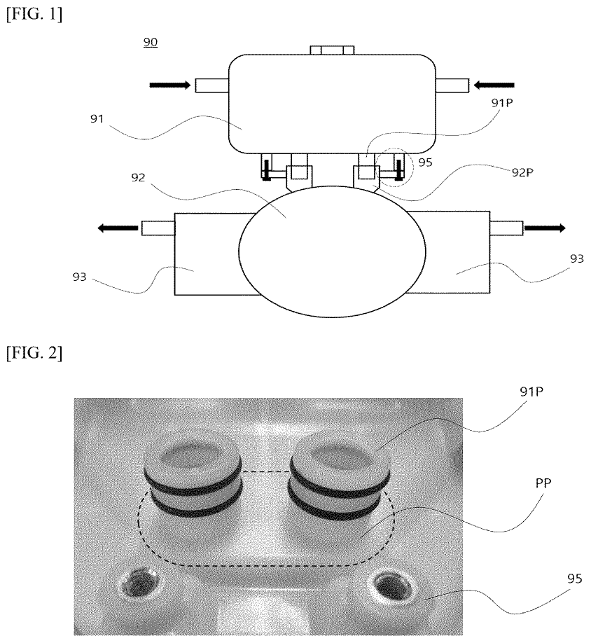

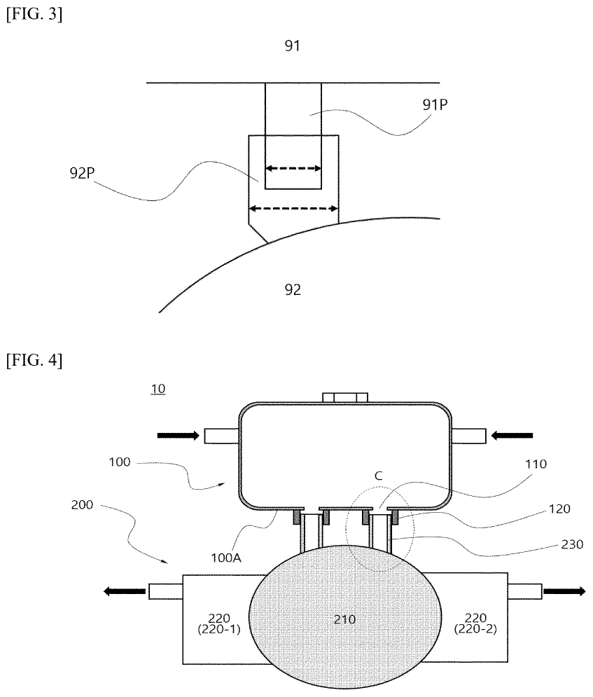

### MODE FOR INVENTION

Hereinafter, the present invention will be described with reference to the accompanying drawings.

FIG. 4 is a view illustrating an integrated coolant module according to one embodiment of the present invention, and as illustrated, an integrated coolant module 10 of the present invention includes a reservoir tank 100 and a coolant control module 200.

The reservoir tank 100 has a hollow therein, and coolant is accommodated and stored in the hollow. An outer wall structure that forms a hollow space of the reservoir tank 100 may be referred to as a tank body. The reservoir tank 100 may have one or more coolant entrance pipes through which coolant enters and exits, and a coolant inlet through which coolant is replenished and a coolant cap for closing the coolant inlet may be provided on an upper portion of the reservoir tank 100.

The coolant control module 200 corresponds to one component of a cooling system in which a valve 210 and a pump 220 are modularized and integrated and includes at least one valve 210 and pump 220. As an example, as illustrated, the coolant control module 200 may be formed in a structure in which the valve 210 is disposed at the center and a first pump 220-1 and a second pump 220-2 are disposed at both sides thereof. The valve 210 may be a multi-directional automation valve 210 for controlling a flow path of the coolant, and the pump 220 may be the coolant pump 220 for pressing and transporting the coolant. In addition, although not illustrated, the coolant control module 200 may further include a controller for controlling the valve 210 and the pump 220, and the corresponding controller may be formed of a printed circuit board (PCB) having electronic components and disposed at one side of the coolant control module 200. In addition, although not illustrated, the coolant control module 200 may further include a housing that accommodates the controller in addition to the valve 210 and the pump 220. The coolant control module 200 is mounted and coupled to one side of the reservoir tank 100, for example, a lower portion of the reservoir tank 100, to form the integrated coolant module 10 along with the reservoir tank 100.

Referring to FIG. 4, the coolant stored in the reservoir tank 100 may flow to the valve 210 of the coolant control module 200, the coolant flowing from the valve 210 to the first pump 220-1 may circulate a first coolant path passing through a battery in a method that is discharged through the coolant entrance pipe of the first pump 220-1, passes through a battery, and then is re-introduced through a first coolant entrance pipe of the reservoir tank 100, and the coolant flowing from the valve 210 to the second pump 220-2 may circulate a second coolant path passing through electronic parts in a method that is discharged through the coolant entrance pipe of the second pump 220-2, passes through the electronic parts, and then is re-introduced through a second coolant entrance pipe of the reservoir tank 100.

In this case, the integrated coolant module 10 of the present invention is configured to form the through-hole 110 at the reservoir tank 100 side, form a coolant pipe 230 at the coolant control module 200 side, and connect the through-hole 110 to the coolant pipe 230 so that the coolant flows between the reservoir tank 100 and the coolant control module 200.

Specifically, the through-hole 110 that penetrates one surface 100A of the reservoir tank (e.g., a lower surface of the tank body) as a coolant entrance may be formed at the coolant control module 200 side, and the coolant pipe 230 formed to protrude from one side of the coolant control module 200 (e.g., an upper portion of the valve 210 or the pump 220 or an upper portion of the above-described housing of the coolant control module 200) as a coolant entrance may be provided at the coolant control module 200 side. In addition, the through-hole 110 and the coolant pipes 230 are connected so that the coolant may flow between the reservoir tank 100 and the coolant control module 200, that is, between the reservoir tank 100 and the valve 210 or between the reservoir tank 100 and the pump 220.

As described in the background art, conventionally, an entrance pipe is formed at each of the reservoir tank side and the valve side (i.e., the coolant control module side) and the two entrance pipes are coupled by being inserted into each other, while the present invention differs from the related art in that the coolant entrance at the reservoir tank 100 side is formed as the through-hole 110. This is intended to overcome the above-described problems of the related art, and more detailed description will be described below.

Hereinafter, a coolant connection structure between the through-hole 110 at the reservoir tank 100 side and the coolant pipe 230 at the coolant control module 200 side will be described in detail.

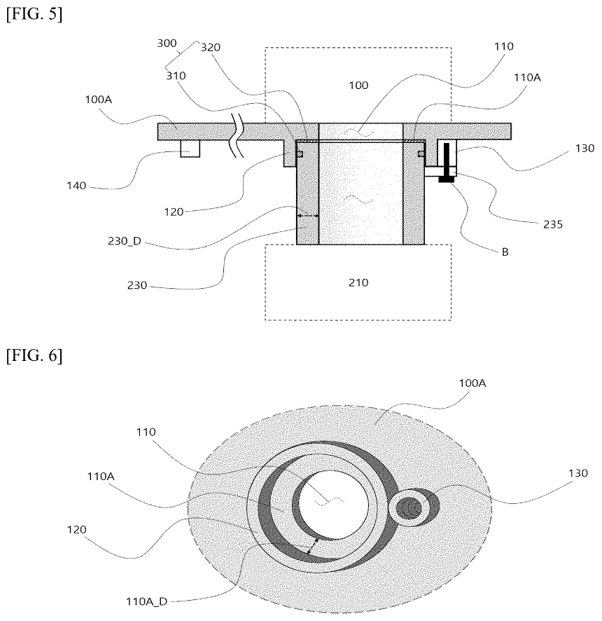

FIG. 5 is an enlarged view of portion C in FIG. 4, and FIG. 6 is a perspective view illustrating one surface of the reservoir tank of portion C in FIG. 4. As illustrated, the coolant connection structure of the present invention may be formed in a structure in which the protrusion rib 120 of a pipe structure surrounding the through-hole 110 is provided on the one surface 100A of the reservoir tank, and an end portion of the coolant pipe 230 is inserted into the protrusion rib 120. This helps to improve connectivity between the through-hole 110 and the coolant pipe 230 and to reinforce the fixing strength of the coolant pipe 230.

In this case, an inner diameter of the protrusion rib 120 may be formed to be larger than a diameter of the through-hole 110 so that an outer circumferential wall of the protrusion rib 120 may be disposed to be radially spaced a predetermined distance from the through-hole 110. That is, the protrusion rib 120 and the through-hole 110 are disposed concentrically, and the inner diameter of the protrusion rib 120 is formed to be larger than the diameter of the through-hole 110 so that the outer circumferential wall of the protrusion rib 120 is radially spaced the predetermined distance from the through-hole 110 to surround the circumference of the through-hole 110. Accordingly, a ring-shaped ring portion 110A of the one surface 100A of the reservoir tank may be formed between the outer circumferential wall of the protrusion rib 120 and the through-hole 110, and a front end of the coolant pipe 230 inserted into the protrusion rib 120 may be seated in the corresponding ring portion 110A.

By adopting such a structure, a constant width of the coolant passage between the reservoir tank 100 and the valve 210 may be formed. Specifically, an inner diameter of the coolant pipe 230 and the diameter of the through-hole 110 are formed to be the same, and thus the constant width of the coolant passage may be formed at a connection point between the two components. As a preferred example, a thickness 230_D of the coolant pipe 230 may be formed to be equal to a width 110A_D of the ring portion 110A so that the inner diameter of the coolant pipe 230 and the diameter of the through-hole 110 may be formed to be the same, thereby solving a conventional pressure loss problem occurring at the connection point between the two pipes due to a difference between the inner diameter of the pipe at the reservoir tank side and the inner diameter of the pipe at the valve 210.

Meanwhile, the present invention limitedly describes a case in which the through-hole 110, the protrusion rib 120, and the coolant pipe 230 are circular or cylindrical, but it is apparent that a polygonal structure may also be applied.

Referring back to FIGS. 4 to 6, the one surface 100A of the reservoir tank may be formed to have a uniform thickness over the entire area. That is, the present invention may be formed in not a structure in which a predetermined area of one surface of the reservoir tank (i.e., one surface of the tank body) is formed to be thicker than other areas and a through-hole is formed in the thickly formed area, but a structure in which the through-hole 110 is directly formed in the one surface 100A of the reservoir tank, which generally has a uniform thickness without such processing. In addition, the protrusion rib 120 is formed near the through-hole 110 of such a structure. This differs from a general coolant pipe structure or a through-hole structure formed at the reservoir tank side in the related art and may provide advantages in terms of structure or manufacturing accordingly.

Referring back to FIG. 5, a seal structure 300 for sealing coolant to prevent external leakage of the coolant may be provided on the connection portion between the protrusion rib 120 and the coolant pipe 230. The seal structure 300 of the present invention may include an O-ring 310 interposed between an inner circumferential surface of the protrusion rib 120 and an outer circumferential surface of the coolant pipe 230 to seal the coolant pipe 230 with a lateral pressure, and a ring gasket 320 interposed between the ring portion 110A and the front end of the coolant pipe 230 to seal the coolant pipe 230 with a surface pressure. One of the O-ring 310 and the ring gasket 320 or a combination of the two may be applied to the connection portion between the protrusion rib 120 and the coolant pipe 230.

In this case, the O-ring 310 and the ring gasket 320 may each be selectively applied to a different connection portion. That is, the through-hole 110, the protrusion rib 120, and the coolant pipe 230 may form one set, multiple sets may be formed, and at least one of them may adapt only the O-ring 310, and the other may adapt only the ring gasket 320. Referring to FIG. 4, the through-hole 110, the protrusion rib 120, and the coolant pipe 230 may each be formed as two to form two sets, and when the two sets are each referred to as a first set connection portion and a second set connection portion, the first set connection portion may be provided with only the O-ring 310 among the O-ring 310 and the ring gasket 320, and the second set connection portion may be provided with only the ring gasket 320 among the O-ring 310 and the ring gasket 320.

In general, it is structurally difficult to fixedly insert two or more coolant pipes into two or more different pipes along with the O-ring, but the present invention can greatly improve the assemblability of the corresponding structure and at the same time, ensure airtightness performance by applying only the O-ring 310 to one coolant pipe 230 and only the ring gasket 320 to the other coolant pipe 230 when inserting each of two or more coolant pipes 230 into each of two or more protrusion ribs 120.

Next, the fixing structure between the through-hole 110 at the reservoir tank 100 side and the coolant pipe 230 at the coolant control module 200 side will be described in detail.

The integrated coolant module 10 of the present invention may adapt the fixing structure for fixing the coolant pipe 230 inserted into the protrusion rib 120. Referring back to FIGS. 5 and 6, a fixing block 130 for fixing the coolant pipe 230 to the protrusion rib 120 may be provided on the one surface 100A of the reservoir tank and near the protrusion rib 120, and a fixing bracket 235 formed at a position corresponding to the fixing block 130 may be provided on the coolant pipe 230. A screw groove may be formed in the fixing block 130 or an insert or the like may be inserted, and the fixing bracket 235 may be formed in a structure formed to extend from the outer circumferential surface of the coolant pipe 230, and the fixing bracket 235 and the fixing block 130 may be bolting-coupled using the fixing member such as a bolt B or the like in a state of being in close contact with each other so that the coolant pipe 230 may be firmly fixed to the protrusion rib 120.

In this case, as illustrated in FIGS. 5 and 6, the fixing block 130 may be disposed adjacent to the protrusion rib 120. Specifically, the fixing block 130 may be formed to protrude outward from the one surface 100A of the reservoir tank, and at least a part of the fixing block 130 may be formed to be in contact with an outer circumferential surface of the protrusion rib 120. That is, there is conventionally a problem that, by adopting a pipe-pipe coupling structure, the fixing structure for fixing the reservoir tank 100 and the valve 210 cannot be installed close to the corresponding pipe due to reasons such as undercut, but as described above, in the present invention, since the mold required space for forming the pipe is not required by having the through-hole 110 and the protrusion rib 120 at the reservoir tank 100 side, the fixing block 130 may be very close to the rib structure near the through-hole 110, specifically, at least one side of the fixing block 130 may be in close contact with the rib structure, thereby providing advantages such as securing spatiality, ease of coupling, and the like in the integrated coolant module.

Furthermore, as illustrated in FIGS. 5 and 6, a height of the fixing block 130, that is, a height at which the fixing block 130 protrudes outward from the one surface 100A of the reservoir tank, may be formed to be equal to a height of the protrusion rib 120, that is, a height at which the outer circumferential wall of the protrusion rib 120 protrudes outward from the one surface 100A of the reservoir tank, which can improve space utilization and structural stability.

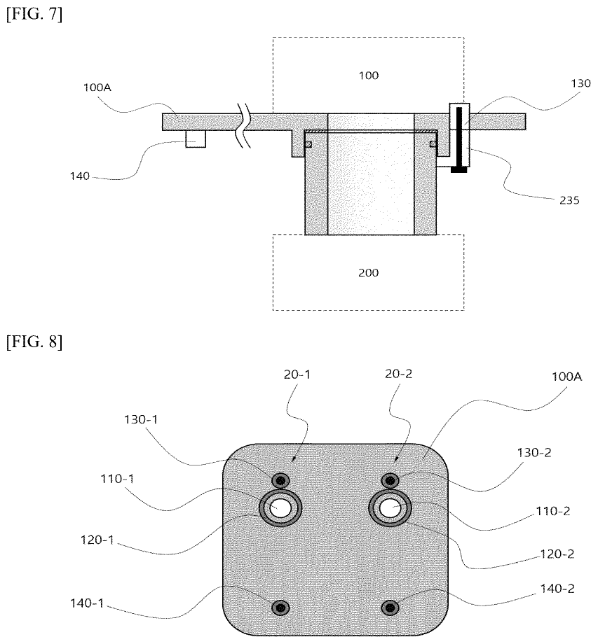

FIG. 7 is a view for describing a fixing structure according to another embodiment of the present invention, and as illustrated, the fixing block 130 may be formed to protrude inward from the one surface 100A of the reservoir tank. This helps to simplify the structure of the outer side of the one surface 100A of the reservoir tank, thereby further improving space utilization of the integrated coolant module 10. Here, the fixing bracket 235 provided on the coolant pipe 230 may be formed in a structure that is formed extend toward the fixing block 130 to be in close contact with the fixing block 130 to surround the outer circumferential surface of the protrusion rib 120, which can help increase the fixing strength between the coolant pipe 230 and the protrusion rib 120.

In this case, even in the present embodiment, the fixing block 130 may be disposed as close as possible to the protrusion rib 120, and specifically, at least a part of the fixing block 130 may be positioned colinearly with the outer circumferential wall of the protrusion rib 120. That is, at least a part of the fixing block 130 may be positioned on an extension line in a height direction of the outer circumferential wall of the protrusion rib 120, and the advantage of the fixing rib being disposed close to the protrusion rib 120 in this way is as described above.

Meanwhile, the integrated coolant module 10 of the present invention may further have an additional fixing structure for fixing the reservoir tank 100 and the coolant control module 200. Specifically, referring back to FIG. 5, an additional fixing block 140 for fixing the coolant control module 200 and the reservoir tank 100 may be provided on the one surface 100A of the reservoir tank, and although not illustrated, the coolant control module 200 may have an additional fixing bracket having one side fixed to the coolant control module 200 side and the other side coupled to the additional fixing block 140. The additional fixing block 140 may have a screw groove formed or an insert inserted like the fixing block 130, and by bolting-coupling the additional fixing bracket to the additional fixing block 140, the coolant control module 200 and the reservoir tank 100 may be more firmly fixed.

Here, the additional fixing block 140 may be disposed to face the fixing block 130. That is, the additional fixing block 140 may be disposed in a direction opposite to the fixing block 130 so that the through-hole 110 and the protrusion rib 120 are disposed between the additional fixing block 140 and the fixing block 130. The additional fixing block 140 may be preferably spaced apart from the protrusion rib 120 and disposed on the one surface 100A of the reservoir tank, but is not limited thereto, and may be disposed at any other position of the reservoir tank 100 to face the fixing block 130. In this way, since the additional fixing block 140 is positioned in the direction opposite to the fixing block 130 with respect to the through-hole 110, the fixing strength between the reservoir tank 100 side and the coolant control module 200 side can be balanced.

FIG. 8 is a view illustrating the one surface 100A of the reservoir tank according to one embodiment of the present invention, and as described above, the through-hole 110 and the protrusion rib 120 may each be formed as two, and correspondingly, the fixing block 130 and the additional fixing block 140 may each be formed as two as well. In this case, when components at the left of the drawing are referred to as a first configuration and components at the right thereof are referred to as a second configuration, one first fixing block 130-1 may be provided corresponding to a first through-hole 110-1 or a first protrusion rib 120-1, and one second fixing block 130-2 may be provided corresponding to a second through-hole 110-2 or a second protrusion rib 120-2. That is, the number of fixing blocks 130 is formed to be equal to the number of protrusion ribs 120, and each fixing block 130 may be provided on each protrusion rib 120 so that each fixing block 130 corresponds one-to-one to each protrusion rib 120.

In addition, one first fixing block 130-1 and one second fixing block 130-2 may be disposed at the same position with respect to the first protrusion rib 120-1 and the second protrusion rib 120-2, respectively, and disposed parallel to each other, and the first additional fixing block 140-1 and the second additional fixing block 140-2 may be disposed opposite to the first fixing block 130-1 and the second fixing block 130-2, respectively, and disposed parallel to each other. As the fixing blocks 130 and the additional fixing blocks 140 are disposed in this way, balance between the reservoir tank 100 side and the coolant control module 200 side may be further improved.

Meanwhile, the reservoir tank 100 of the present invention may be manufactured by injection molding and formed of a resin material, and in this case, the through-hole 110 and the protrusion rib 120, and furthermore, the fixing block 130 and the additional fixing block 140 may be manufactured by injection molding along with the tank body and formed integrally. The reason for adopting a structure in which the through-hole 110 is formed in the tank body, the protrusion rib 120 is formed near the through-hole 110, and the coolant pipe 230 at the coolant control module 200 side is inserted into the corresponding protrusion rib 120 and connected to the through-hole 110 and the effect accordingly are as described above.

Although the embodiments of the present invention have been described above with reference to the accompanying drawings, those skilled in the art to which the present invention pertains will understand that the present invention can be carried out in other specific forms without changing the technical spirit or essential features thereof. Accordingly, it should be understood that the above-described embodiments are illustrative and not restrictive in all aspects.

### Description of Drawing Symbols

10: integrated coolant module
100: reservoir tank
100A: one surface of reservoir tank
110: through-hole
120: protrusion rib
130: fixing block
140: additional fixing block
200: coolant control module
210: valve
220: pump
230: coolant pipe
235: fixing bracket
300: seal structure
310: O-ring
320: ring gasket

1. An integrated coolant module comprising:
a reservoir tank in which coolant is stored; and
a coolant control module including a valve and a pump,
wherein a through-hole that penetrates one surface of the reservoir tank as a coolant entrance is formed at the reservoir tank side,
a coolant pipe formed to protrude from one side of the coolant control module as a coolant entrance is provided at the coolant control module side, and
the through-hole and the coolant pipe are connected and formed so that coolant flows between the reservoir tank and the coolant control module.

2. The integrated coolant module of claim 1, wherein a protrusion rib having a pipe structure surrounding the through-hole is provided on the one surface of the reservoir tank,
an inner diameter of the protrusion rib is formed to be larger than a diameter of the through-hole so that an outer circumferential wall of the protrusion rib is disposed to be radially spaced a predetermined distance from the through-hole, and a ring-shaped ring portion of the one surface of the reservoir tank is formed between the protrusion rib and the through-hole, and
an end portion of the coolant pipe is inserted into the protrusion rib.

3. The integrated coolant module of claim 2, wherein an inner diameter of the coolant pipe is equal to the diameter of the through-hole.

4. The integrated coolant module of claim 2, wherein a thickness of the coolant pipe is equal to a width of the ring portion.

5. The integrated coolant module of claim 2, wherein a front end of the coolant pipe is seated on the ring portion.

6. The integrated coolant module of claim 2, wherein a connection portion between the protrusion rib and the coolant pipe is provided with
at least one of an O-ring interposed between an inner circumferential surface of the protrusion rib and an outer circumferential surface of the coolant pipe to seal the coolant pipe with a lateral pressure, and
a ring gasket interposed between the ring portion and a front end of the coolant pipe to seal the coolant pipe with a surface pressure.

7. The integrated coolant module of claim 6, wherein the through-hole, the protrusion rib, and the coolant pipe are each formed as two, and
when one of the two through-holes is referred to as a first through-hole and the other is referred to as a second through-hole, a protrusion rib corresponding to the first through-hole among the two protrusion ribs is referred to as a first protrusion rib and a protrusion rib corresponding to the second through-hole is referred to as a second protrusion rib, and a coolant pipe corresponding to the first through-hole among the two coolant pipes is referred to as a first coolant pipe and a coolant pipe corresponding to the second through-hole is referred to as a second coolant pipe,
one of a first connection portion between the first protrusion rib and the first coolant pipe and a second connection portion between the second protrusion rib and the second coolant pipe has only the O-ring among the O-ring and the ring gasket, and the other has only the ring gasket among the O-ring and the ring gasket.

8. The integrated coolant module of claim 2, wherein a fixing block for fixing the coolant pipe to the protrusion rib is provided on the one surface of the reservoir tank and near the protrusion rib,
the coolant pipe is provided with a fixing bracket to correspond to the fixing block so that the coolant pipe inserted into the protrusion rib is fixed through the fixing block and the fixing bracket, and
the fixing block is disposed adjacent to the protrusion rib.

9. The integrated coolant module of claim 8, wherein the fixing block is formed to protrude outward from the one surface of the reservoir tank, and
at least a part of the fixing block is in contact with an outer circumferential surface of the protrusion rib.

10. The integrated coolant module of claim 9, wherein a height of the fixing block is equal to a height of the protrusion rib.

11. The integrated coolant module of claim 8, wherein the fixing block is formed to protrude inward from the one surface of the reservoir tank, and
at least a part of the fixing block is positioned colinearly with an outer circumferential wall of the protrusion rib.

12. The integrated coolant module of claim 8, wherein the fixing block is formed as one corresponding to the protrusion rib.

13. The integrated coolant module of claim 8, wherein the reservoir tank is provided with an additional fixing block for fixing the coolant control module and the reservoir tank, and
the additional fixing block is disposed in a direction opposite to the fixing block so that the through-hole is disposed between the additional fixing block and the fixing block.

14. The integrated coolant module of claim 2, wherein the one surface of the reservoir tank is formed to have a constant thickness over the entire area.

15. The integrated coolant module of claim 2, wherein the reservoir tank and the protrusion rib are manufactured by injection-molding and formed integrally.
